(19) United States
(12) Patent Application Publication
(10) Pub. No.: US 2025/0218918 A1
(43) Pub. Date: Jul. 3, 2025

(54) ELECTRONIC DEVICE

(71) Applicant: Renesas Electronics Corporation, Tokyo (JP)

(72) Inventors: Ryuichi OIKAWA, Tokyo (JP); Shuuichi KARIYAZAKI, Tokyo (JP)

(21) Appl. No.: 18/937,183

(22) Filed: Nov. 5, 2024

(30) Foreign Application Priority Data
Dec. 27, 2023 (JP) 2023-221744

(51) Int. Cl. H01L 23/498; H01L 23/00; H01L 25/18; H05K 1/11; H10B 80/00

(52) U.S. Cl. CPC H01L 23/49838; H01L 23/49827; H01L 25/18; H05K 1/115; H10B 80/00; H01L 24/16; H01L 2224/16235; H01L 2225/06517; H01L 2924/1511; H05K 2201/10159

(57) ABSTRACT

A plurality of wirings included in a wiring substrate includes: a plurality of first wirings for propagating a first clock signal and a first chip select signal to first and second memory devices mounted on a front surface; and a plurality of second wirings for propagating a second clock signal and a second chip select signal to third and fourth memory devices mounted on a back surface. The plurality of first wirings is provided in a wiring layer, which is closer to the front surface, of a plurality of wiring layers, and the plurality of second wirings is provided in a wiring layer, which is closer to the back surface, of the wiring layers.

### CROSS-REFERENCE TO RELATED APPLICATION

The disclosure of Japanese Patent Application No. 2023-221744 filed on Dec. 27, 2023, including the specification, drawings and abstract is incorporated herein by reference in its entirety.

### BACKGROUND

The present invention relates to an electronic device, and relates to, for example, an electronic device including a control device and a plurality of memory devices mounted on a wiring substrate.

There is disclosed a technique listed below.
[Patent Document 1] Japanese Unexamined Patent Application Publication No. 2015-35159

The Patent Document 1 discloses an electronic device capable of moderating influences of signal reflection even if branch wirings for fly-by topology are long. The electronic device includes a mounting substrate on which a plurality of first semiconductor components and a second semiconductor component for controlling the first semiconductor components are mounted. The mounting substrate includes a main wiring and branch wirings electrically for connecting the second semiconductor component and the first semiconductor components. Chip resistors are connected in series at the middle of the branch wirings leading to the first semiconductor components.

### SUMMARY

In recent years, there is the need to downsize the electronic devices, in other words, to reduce a mounting area of each device in a wiring substrate. Additionally, particularly along with higher speed of the electronic device, there is the need to improve waveform integrity (quality) of each signal propagating in the wiring substrate. As a method for improving the waveform integrity, a method of providing a resistor device for use in attenuating reflected signals is proposed as described in, for example, the Patent Document 1. However, by the resistor device, the mounting area is increased. Thus, a mechanism to improve the waveform integrity without providing such a resistor device is awaited.

Other objects and novel characteristics will become apparent from the description of the present specification and the drawings.

An electronic device according to one embodiment includes: a wiring substrate having a first surface, a second surface opposite the first surface, a plurality of wiring layers and a plurality of wirings; a first memory device and a second memory device mounted on the first surface; a third memory device and a fourth memory device mounted on the second surface; and a control device. The control device is mounted on the first surface, is configured to access each of the first and second memory devices by using a common first clock signal and a common first chip select signal, and is configured to access each of the third and fourth memory devices by using a common second clock signal and a common second chip select signal. The plurality of wirings includes: a plurality of first wirings through which the common first clock signal and the common first chip select signal are propagated; and a plurality of second wirings through which the common second clock signal and the common second chip select signal are propagated. The plurality of first wirings is provided in a wiring layer, which is closer to the first surface than the second surface, of the plurality of wiring layers, and the plurality of second wirings is provided in a wiring layer, which is closer to the second surface than the first surface, of the wiring layers.

The waveform integrity of the signal can be improved by using an electronic device according to one embodiment.

### BRIEF DESCRIPTIONS OF THE DRAWINGS

FIG. 1A is a plan view illustrating an exemplary schematic configuration of an electronic device according to a first embodiment.

FIG. 1B is a plan view illustrating an exemplary schematic configuration of the electronic device according to the first embodiment.

FIG. 2 is a plan view illustrating an exemplary configuration of an interesting partial region in FIGS. 1A and 1B.

FIG. 3 is a circuit diagram illustrating exemplary connections between memory interfaces and memory devices in FIG. 2.

FIG. 4A is a cross-sectional view illustrating an exemplary schematic configuration for clock signals and chip select signals along the line A-A′ of FIG. 2.

FIG. 4B is a cross-sectional view illustrating an exemplary schematic configuration for clock signals and chip select signals along the line B-B′ of FIG. 2.

FIG. 5 is a cross-sectional view illustrating an exemplary schematic configuration for command address signals along the line A-A′ of FIG. 2.

FIG. 6 is an impedance chart illustrating an exemplary impedance property of a via section for signal propagation and an open stub in FIGS. 4A and 4B.

FIG. 7 is a diagram illustrating exemplary results of calculation for how much a quarter length of a wavelength “A” of a propagation signal depends on a Nyquist frequency.

FIG. 8A is a circuit diagram illustrating an exemplary equivalent configuration for signal propagation paths to rank 1 in FIG. 4A.

FIG. 8B is a timing chart conceptually illustrating a mechanism of cancelling reflected signals in FIG. 8A.

FIG. 9 is a waveform diagram illustrating exemplary simulation results targeting a memory device closer to the control device in FIG. 4A and resulted from observation of input waveforms of a chip select signal.

FIG. 10 is a waveform diagram illustrating exemplary simulation results targeting a memory device closer to and a memory device farther from the control device in FIG. 4A and resulted from observation of input waveforms of a clock signal.

FIG. 11A is a cross-sectional view illustrating a more-detailed exemplary configuration along the line A-A′ of FIG. 2.

FIG. 11B is a cross-sectional view illustrating a more-detailed exemplary configuration along the line B-B′ of FIG. 2.

FIG. 12 is a cross-sectional view illustrating an extended exemplary configuration of a configuration of FIG. 4A.

FIG. 13 is a cross-sectional view illustrating an exemplary schematic configuration for clock signals, chip select signals and command address signals along the line A-A′ of FIG. 2 in an electronic device according to a second embodiment.

FIG. 14 is a table illustrating combinations with “n” and “m” to be avoided, for the wiring length between the control device and a memory device of FIG. 13.

FIG. 15A is a diagram for schematically explaining exemplary problems in a typical electronic device.

FIG. 15B is a diagram for schematically explaining exemplary problems in a typical electronic device.

FIG. 16 is a diagram illustrating exemplary waveforms of clock signals input by two memory devices in FIG. 15A.

FIG. 17A is a cross-sectional view illustrating an exemplary configuration of an electronic device according to a comparative example, as different from that of FIG. 4A.

FIG. 17B is a cross-sectional view illustrating an exemplary configuration of the electronic device according to the comparative example, as different from that of FIG. 4B.

### DETAILED DESCRIPTION

In the embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Also, in the embodiments described below, when referring to the number of elements (including number of pieces, values, amount, range, and the like), the number of the elements is not limited to a specific number unless otherwise stated or except the case where the number is apparently limited to a specific number in principle. The number larger or smaller than the specified number is also applicable.

Further, in the embodiments described below, it goes without saying that the components (including element steps) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, the embodiments will be described in detail with reference to the drawings. Note that components having the same function are denoted by the same reference symbols throughout all the drawings for describing the embodiments, and the repetitive description thereof is omitted. In addition, the description of the same or similar portions is not repeated in principle unless otherwise particularly required in the following embodiments.

### First Embodiment

### <Outline of Entire Electronic Device>

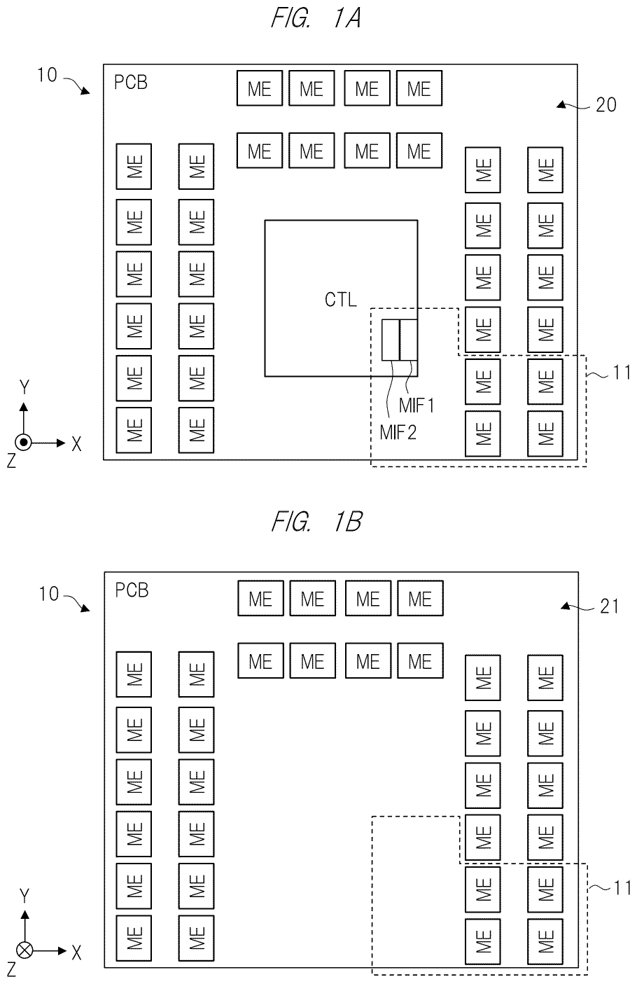

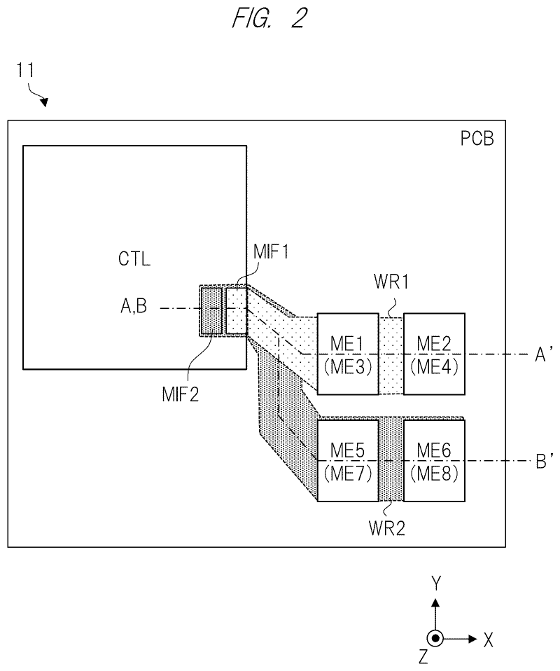

FIGS. 1A and 1B are plan views each illustrating an exemplary schematic configuration of an electronic device according to a first embodiment. An electronic device 10 illustrated in FIGS. 1A and 1B includes a wiring substrate PCB, a plurality of memory devices ME, and a control device CTL. The electronic device 10 is particularly applicable to signal processing apparatuses or information processing apparatuses such as data centers, network base stations, and game terminals that require broadband and large-capacity memories.

The wiring substrate PCB has a front surface (first surface) 20, a back surface (second surface) 21 opposite the front surface 20, a plurality of wiring layers and a plurality of wirings. FIGS. 1A and 1B illustrate the exemplary configurations of the front surface 20 and the back surface 21 of the wiring substrate PCB, respectively. In the present specification, the mutually orthogonal directions are assumed as an X-axis direction, a Y-axis direction, and a Z-axis direction, and planar directions of the wiring substrate PCB are called the X-axis direction and the Y-axis direction while a thickness direction of the wiring substrate PCB is called the Z-axis direction.

Each of the memory devices ME is, for example, a double data rate 5_synchronous dynamic random access memory (DDR5_SDRAM) or the like. In this example, 32 memory devices ME are mounted on each of the front surface 20 and the back surface 21 of the wiring substrate PCB. The 32 memory devices ME mounted on the front surface 20 are arranged in the form of, for example, two rows by 16 columns along the outer periphery (three sides of the four sides) of the wiring substrate PCB. The 32 memory devices ME mounted on the back surface 21 are arranged to face the 32 memory devices ME mounted on the front surface 20 in the Z-axis direction.

The control device CTL is, for example, a system on chip (SoC) or the like including various circuit blocks typified by a processor. The control device CTL is mounted on the front surface 20 of the wiring substrate PCB, and is arranged near the center of the wiring substrate PCB in this example. The control device CTL includes a plurality of memory interfaces for accessing the memory devices ME. In this example, two memory interfaces MIF1 and MIF2 of the memory interfaces are illustrated.

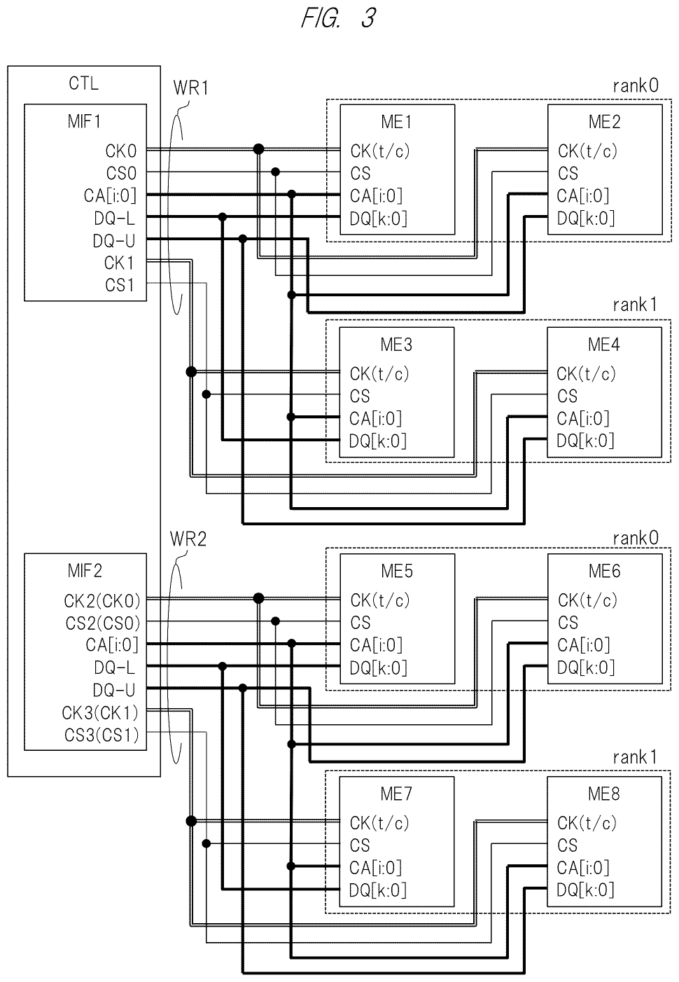

FIG. 2 is a plan view illustrating an exemplary configuration of an interesting partial region 11 in FIGS. 1A and 1B. In FIG. 2, the memory interface MIF1 is connected through a plurality of wirings WR1 in the wiring substrate PCB to two memory devices ME1 and ME2 mounted on the front surface 20 of the wiring substrate PCB and two memory devices ME3 and ME4 mounted on the back surface 21 facing these memory devices. Similarly, the memory interface MIF2 is connected through a plurality of wirings WR2 in the wiring substrate PCB to two memory devices ME5 and ME6 mounted on the front surface 20 of the wiring substrate PCB and two memory devices ME7 and ME8 mounted on the back surface 21 facing these memory devices.

The two memory devices ME1 and ME2 are arranged side by side in the X-axis direction. The two memory devices ME5 and ME6 are also arranged side by side in the X-axis direction. The memory device ME1 and the memory device ME5 are arranged side by side in the Y-axis direction in a region closer to the control device CTL. The memory device ME2 and the memory device ME6 are arranged side by side in the Y-axis direction in a region farther from the control device CTL.

The memory interfaces MIF1 and MIF2 are arranged side by side in the X-axis direction. The memory interface MIF2 and its external terminal are arranged to be closer to an inside of the control device CTL than the memory interface MIF1 and its external terminal. In other words, the memory interface MIF1 is arranged closer to the outer periphery of the control device CTL than the memory interface MIF2.

More specifically, sets of the memory interfaces MIF1 and MIF2 as illustrated in FIG. 2 are arranged side by side along the outer periphery of the control device CTL in FIG. 1A. In the example of FIG. 1A, eight sets of the memory interfaces MIF1 and MIF2 are arranged. Since the memory interfaces MIF1 and MIF2 are arranged side by side in not the Y-axis direction but the X-axis direction as described above, the outer periphery of the control device CTL can be shortened, thereby downsizing the control device CTL and consequently the electronic device 10.

FIG. 3 is a circuit diagram illustrating exemplary connections between the memory interfaces MIF1, MIF2 and the memory devices ME1 to ME8 in FIG. 2. Each of the memory devices ME1 to ME8 mainly inputs/outputs a “k+1”-bit data signal DQ[k:0] in response to input of control signals including a clock signal CK, a chip select signal CS, and an “i+1”-bit command address signal CA [i:0]. More specifically, the clock signal CK is made of a positive-polarity clock signal CK(t) and a negative-polarity clock signal CK(c) configuring a differential pair.

Each of the memory devices ME1, ME2, ME5, and ME6, which are mounted on the front surface 20 of the wiring substrate, configures a memory device of rank 0. Each of the memory devices ME3, ME4, ME7, and ME8, which are mounted on the back surface of the wiring substrate, configures a memory device of rank 1. The memory interface MIF1 accesses the memory devices ME1 and ME2 of rank 0 by using a common clock signal CK0 and a common chip select signal CS0.

The memory interface MIF1 accesses the memory devices ME3 and ME4 of rank 1 by using a common clock signal CK1 and a common chip select signal CS1 which are different from the clock signal CK0 and the chip select signal CS0. Further, the memory interface MIF1 outputs a common command address signal CA to the memory devices ME1 to ME4 of ranks 0 and 1.

When accessing the memory devices ME1 and ME2 of rank 0, the memory interface MIF1 inputs/outputs the data signal DQ of the memory device ME1 as a lower data signal DQ-L, and inputs/outputs the data signal DQ of the memory device ME2 as an upper data signal DO-U. To the contrary, when accessing the memory devices ME3 and ME4 of rank 1, the memory interface MIF1 inputs/outputs the data signal DQ of the memory device ME3 as a lower data signal DQ-L, and inputs/outputs the data signal DQ of the memory device ME4 as an upper data signal DQ-U.

As similar to the memory interface MIF1, the memory interface MIF2 accesses the memory devices ME5 and ME6 of rank 0 by using a common clock signal CK2 and a common chip select signal CS2. The memory interface MIF2 accesses the memory devices ME7 and ME8 of rank 1 by using a common clock signal CK3 and a common chip select signal CS3. Further, the memory interface MIF2 outputs a common command address signal CA to the memory devices ME5 to ME8 of ranks 0 and 1.

When accessing the memory devices ME5 and ME6 of rank 0, the memory interface MIF2 inputs/outputs the data signal DQ of the memory device ME5 as a lower data signal DQ-L, and inputs/outputs the data signal DQ of the memory device ME6 as an upper data signal DQ-U. To the contrary, when accessing the memory devices ME7 and ME8 of rank 1, the memory interface MIF2 inputs/outputs the data signal DQ of the memory device ME7 as a lower data signal DQ-L, and inputs/outputs the data signal DQ of the memory device ME8 as an upper data signal DQ-U.

The clock signal CK0 and the chip select signal CS0 are output at the same time with the clock signal CK2 and the chip select signal CS2. Similarly, the clock signal CK1 and the chip select signal CS1 are output at the same time with the clock signal CK3 and the chip select signal CS3. Therefore, in the relationship between the memory interface MIF2 and the memory devices ME5 to ME8, the clock signals CK2, CK3 and the chip select signals CS2, CS3 may be the clock signals CK0, CK1 and the chip select signals CS0, CS1, respectively.

For example, it is assumed herein that the data signal DQ[k:0] is of eight bits, in other words, one byte. In this case, the control device CTL accesses the memory devices ME of rank 0 in FIG. 1A by using the clock signal CK0 and the chip select signal CS0, thereby inputting/outputting the data signals DQ-L and DQ-U of a total of 32 bytes. Similarly, the control device CTL accesses the memory devices ME of rank 1 in FIG. 1B by using the clock signal CK1 and the chip select signal CS1, thereby inputting/outputting the data signals DO-L and DQ-U of a total of 32 bytes.

### <Schematic Cross-sectional Configuration of Electronic Device>

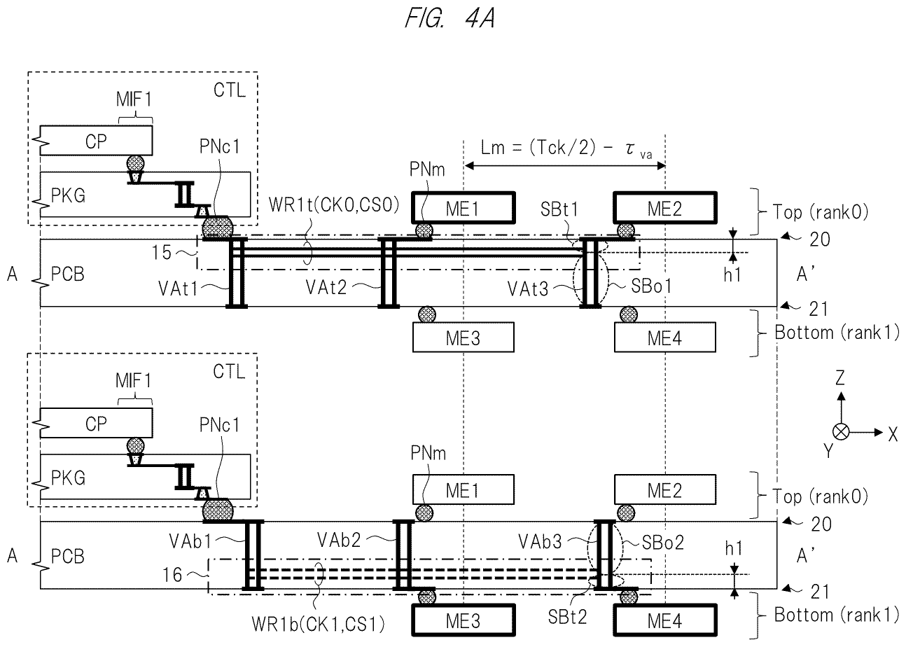

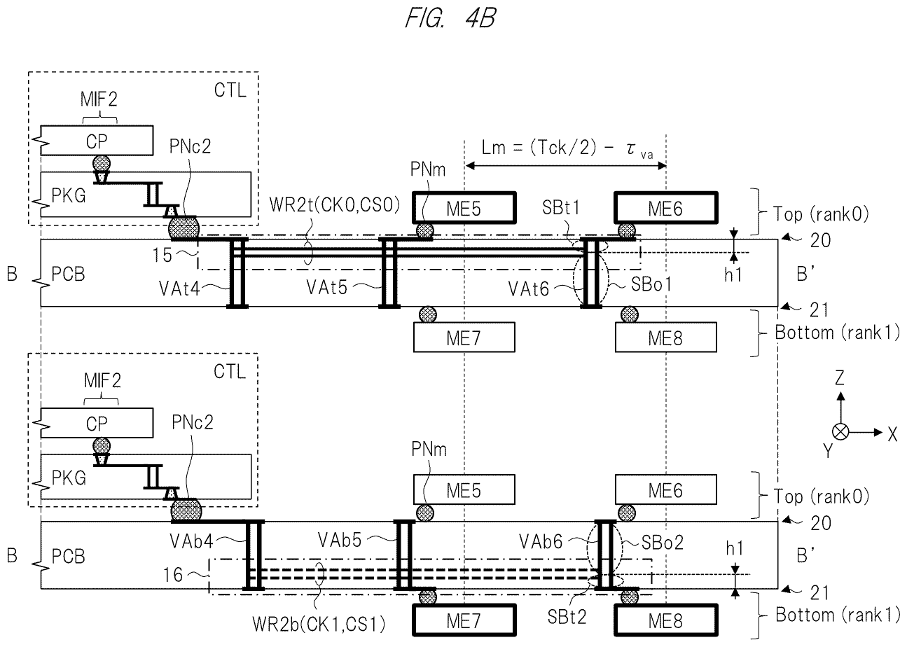

FIG. 4A is a cross-sectional view illustrating an exemplary schematic configuration for clock signals and chip select signals along the line A-A′ of FIG. 2. FIG. 4B is a cross-sectional view illustrating an exemplary schematic configuration for clock signals and chip select signals along the line B-B′ of FIG. 2. The cross-sectional configuration along the line A-A′ is illustrated to be divided into two figures for understandable explanation for the configuration. The same goes for the cross-sectional configuration along the line B-B′.

In FIG. 4A, the control device CTL includes a semiconductor chip CP and a package substrate PKG mounting the semiconductor chip CP thereon. The memory interface MIF1 formed on the semiconductor chip CP is connected to the package substrate PKG through an external terminal of the semiconductor chip CP. The memory interface MIF1 is connected to an external terminal PNc1 of the control device CTL through an internal wiring of the package substrate PKG.

The wiring substrate PCB includes a plurality of wiring layers sequentially stacked through an insulating layer therebetween in the Z-axis direction, a wiring formed in each wiring layer, and a plurality of through via wirings VAt1 to VAt3 and VAb1 to VAb3. In the present specification, the through via wirings are collectively called through via wirings VA. In a gap between the front surface 20 and the back surface 21 of the wiring substrate PCB, the through via wirings VA penetrate through the wiring layers. A plurality of wirings formed in predetermined wiring layers includes a plurality of wirings WR1t and a plurality of wirings WR1b.

Through the wirings WR1t, the clock signal CK0 and the chip select signal CS0, which are propagated from the external terminal PNc1 through the through via wiring VAt1, propagate to the memory devices ME1 and ME2 of rank 0. At this time, the through via wiring VAt2 connects the wirings WR1t to an external terminal PNm of only the memory device ME1 of the memory devices ME1 and ME3. The through via wiring VAt3 connects the wirings WR1t to an external terminal PNm of only the memory device ME2 of the memory devices ME2 and ME4.

To the contrary, through the wirings WR1b, the clock signal CK1 and the chip select signal CS1, which are propagated from the external terminal PNc1 through the through via wiring VAb1, propagate to the memory devices ME3 and ME4 of rank 1. At this time, the through via wiring VAb2 connects the wirings WR1b to an external terminal PNm of only the memory device ME3 of the memory devices ME1 and ME3. The through via wiring VAb3 connects the wirings WR1b to an external terminal PNm of only the memory device ME4 of the memory devices ME2 and ME4.

More specifically, the number of wirings WR1t is three for propagating the paired clock signals CK0 and the chip select signal CS0. The same goes for the number of wirings WR1b. Similarly, the external terminals PNc1, the through via wirings VAt1 to VAt3, and the through via wirings VAb1 to VAb3 are also provided as many as signals.

To the contrary, in FIG. 4B, the memory interface MIF2 formed on the semiconductor chip CP is connected to the package substrate PKG through an external terminal of the semiconductor chip CP. Further, the memory interface MIF2 is connected to an external terminal PNc2 of the control device CTL through an internal wiring of the package substrate PKG. The memory interface MIF2 is formed to be closer to an inside of the semiconductor chip CP than the memory interface MIF1 of FIG. 4A. Accordingly, the external terminal PNc2 is also arranged to be closer to an inside of the control device CTL than the external terminal PNc1 of FIG. 4A.

The wiring substrate PCB includes a plurality of through via wirings VAt4 to VAt6 and VAb4 to VAb6 in addition to the wiring layers and the wirings. A plurality of wirings formed in predetermined wiring layers includes a plurality of wirings WR2t and a plurality of wirings WR2b. Through the wirings WR2t, the clock signal CK0 and the chip select signal CS0, which are propagated from the external terminal PNc2 through the through via wiring VAt4, propagate to the memory devices ME5 and ME6 of rank 0. At this time, the through via wiring VAt5 connects the wirings WR2t to an external terminal PNm of only the memory device ME5 of the memory devices ME5 and ME7. The through via wiring VAt6 connects the wirings WR2t to an external terminal PNm of only the memory device ME6 of the memory devices ME6 and ME8.

To the contrary, through the wirings WR2b, the clock signal CK1 and the chip select signal CS1, which are propagated from the external terminal PNc2 through the through via wiring VAb4, propagate to the memory devices ME7 and ME8 of rank 1. At this time, the through via wiring VAb5 connects the wirings WR2b to an external terminal PNm of only the memory device ME7 of the memory devices ME5 and ME7. The through via wiring VAb6 connects the wirings WR2b to an external terminal PNm of only the memory device ME8 of the memory devices ME6 and ME8. Note that the specific numbers of wirings WR2b and the like are similar as those of FIG. 4A.

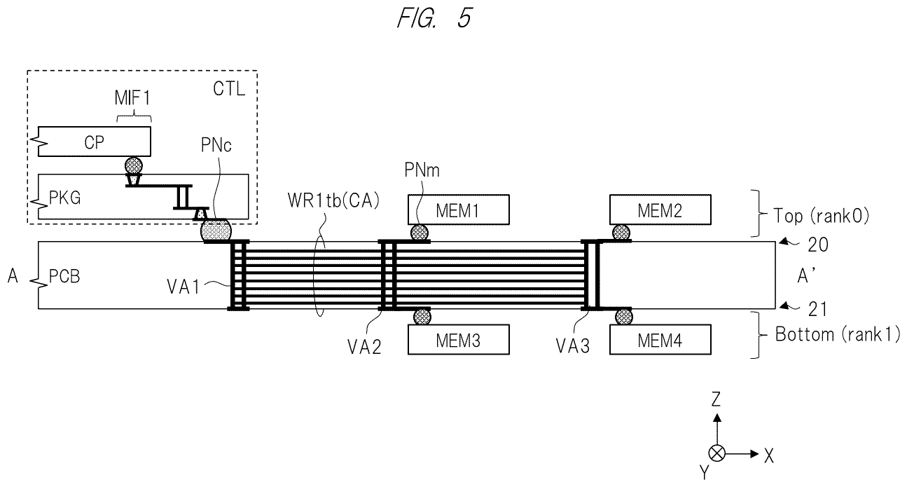

FIG. 5 is a cross-sectional view illustrating an exemplary schematic configuration for command address signals along the line A-A′ of FIG. 2. Although not illustrated, the cross-sectional configuration along the line B-B′ is similar as that of FIG. 5. In FIG. 5, the memory interface MIF1 formed on the semiconductor chip CP is connected to the package substrate PKG through the external terminal of the semiconductor chip CP. Further, the memory interface MIF1 is connected to an external terminal PNc of the control device CTL through an internal wiring of the package substrate PKG. The wiring substrate PCB includes a plurality of through via wirings VA1 to VA3 in addition to the wiring layers and the wirings.

A plurality of wirings formed in predetermined wiring layers includes a plurality of wirings WR1tb. Through the wirings WR1tb, a plurality of command address signals CA, which are propagated from the external terminal PNc through the through via wiring VA1, propagate to the memory devices ME1 to ME4 of ranks 0 and 1. At this time, the through via wiring VA2 commonly connects the wirings WR1tb to the external terminals PNm of the memory devices ME1 and ME3. The through via wiring VA3 commonly connects the wirings WR1tb to the external terminals PNm of the memory devices ME2 and ME4. More specifically, the numbers of wirings WR1tb and the like are defined on the basis of the number of command address signals CA.

### Detail of Issue and Comparative Example

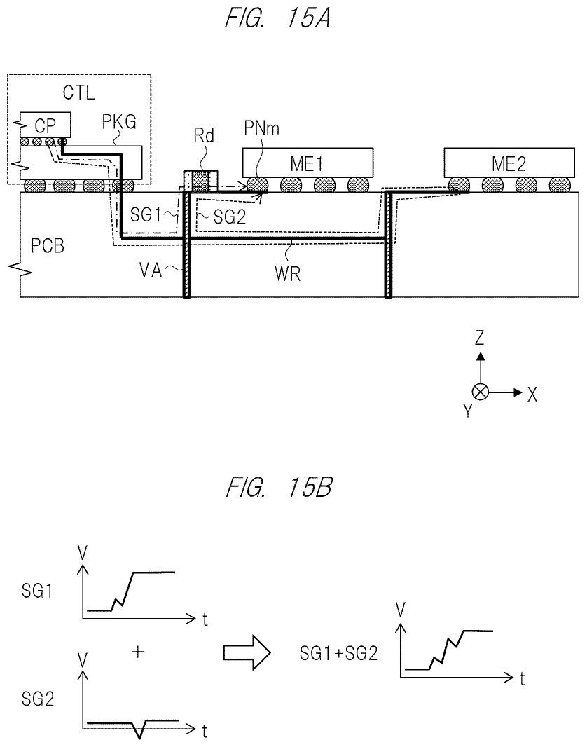

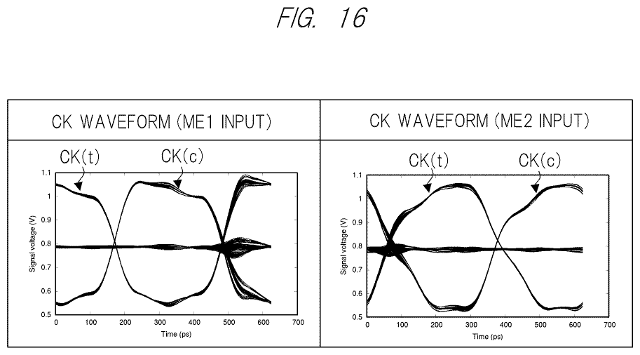

FIGS. 15A and 15B are diagrams each for schematically explaining exemplary problems in a typical electronic device. FIG. 15A illustrates simplified components associated with rank 0 in the exemplary configuration of FIG. 4A. FIG. 15B illustrates exemplary signal waveforms propagated in the configuration of FIG. 15A.

For example, an electronic device configuring a next-generation network processor or the like may need a broadband and large-capacity memory. Thus, as illustrated in FIG. 15A, a wiring WR for propagating a control signal is branched into two by two through via wirings VA, thereby connecting the same wirings WR to the two memory devices ME1 and ME2. Thereby, the small-bit memory can be handled as if the memory was a large-bit memory, thereby achieving the wider band of the memory. Such a system is also called fly-by system.

However, by using the fly-by system, a reflected signal SG2 which is reflected at the branch farther from the control device CTL is overlapped with an input signal SG1 into the memory device ME1 arranged at the branch closer to the control device CTL as illustrated in FIGS. 15A and 15B. Consequently, the waveform integrity of the input signal “SG1+SG2” into the memory device ME1 arranged at the branch closer to the control device CTL is particularly reduced, and there is a risk of an error in the access to the memory device ME1 or the like.

In order to achieve the larger-capacity memory, memory devices ME of two ranks, which are separated by chip select signals CS, may be mounted on both surfaces of the wiring substrate PCB as illustrated in FIG. 4A and the like. Such a system is also called Clamshell. However, along with recent sophisticated systems, the number of wiring layers tends to be large, and the wiring substrate PCB tends to be thick. Accordingly, each length of the through via wirings VA is also increased by using the Clamshell configuration. Consequently, the magnitude of the reflected signal SG2 may further increase, and the waveform integrity may further decrease.

Accordingly, as illustrated in FIG. 15A, a resistor device Rd that is a damping resistor may be inserted in series to the wiring near the external terminal PNm of the memory device ME1 arranged at the closer branch to the control device CTL. Thereby, the reflected signal SG2 caused at the branch farther from the control device CTL attenuates before being input into the memory device ME1 arranged at the branch closer to the control device CTL. However, the resistor device Rd attenuates not only the reflected signal SG2 but also the normal input signal SG1. That is, the attenuation of the normal input signal SG1 and the attenuation of the reflected signal SG2 are put in a trade-off relationship.

The attenuation of the normal input signal SG1 means wasting power. If the resistor devices Rd as illustrated in FIG. 15A are provided as many as the signals, the mounting area in the wiring substrate PCB may increase, and the electronic device may be difficult to be downsized. Further, the cost of components and the like may be increased by the resistor devices Rd mounted. Thus, it is desirable to improve the waveform integrity without providing the resistor device Rd. The through via wirings VA cause signal reflection due to impedance mismatch, and attenuate the transmitting signals as much as reflection. It is also desirable to reduce the signal attenuation as much as possible.

FIG. 16 is a diagram illustrating exemplary waveforms of the clock signals CK input by the two memory devices ME1 and ME2 in FIG. 15A. Still another problem is that the signal reflection is repeated at the branch point by using the fly-by system, thereby causing the waveform of the clock signal CK input by the memory device ME1 and the waveform of the clock signal CK input by the memory device ME2 to be asymmetric to each other. This is because the amount and the timing of the combined reflected signals are different between the side closer to and the farther side from the control device CTL.

In FIG. 16, for example, the waveform of the negative-polarity clock signal CK(c) input into the memory device ME1 and the waveform of the positive-polarity clock signal CK(t) input into the memory device ME2 are desirably equal to each other. In FIG. 16, however, the waveforms are completely different from each other. This results in, for example, a decrease in operation margin.

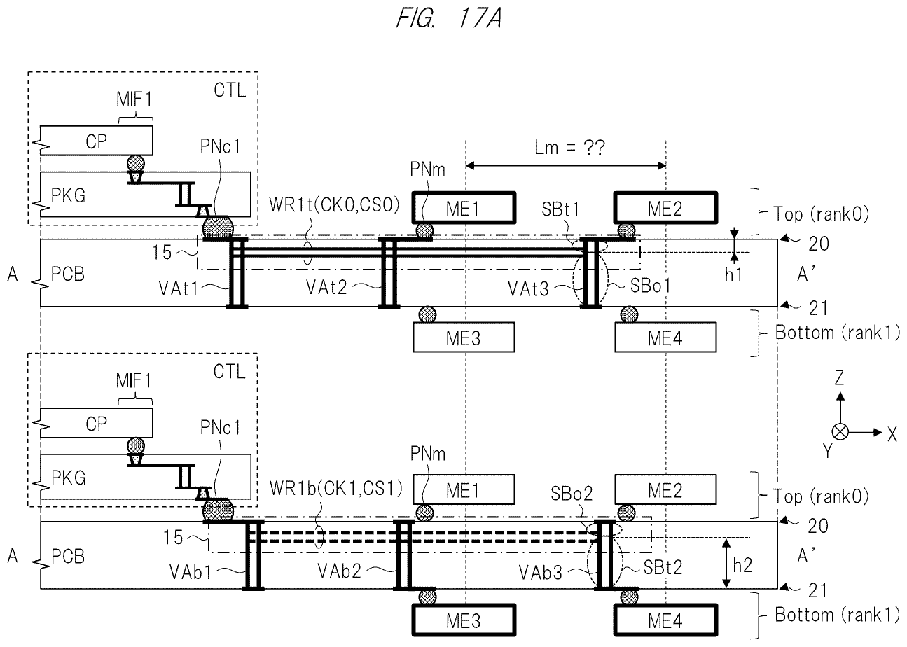

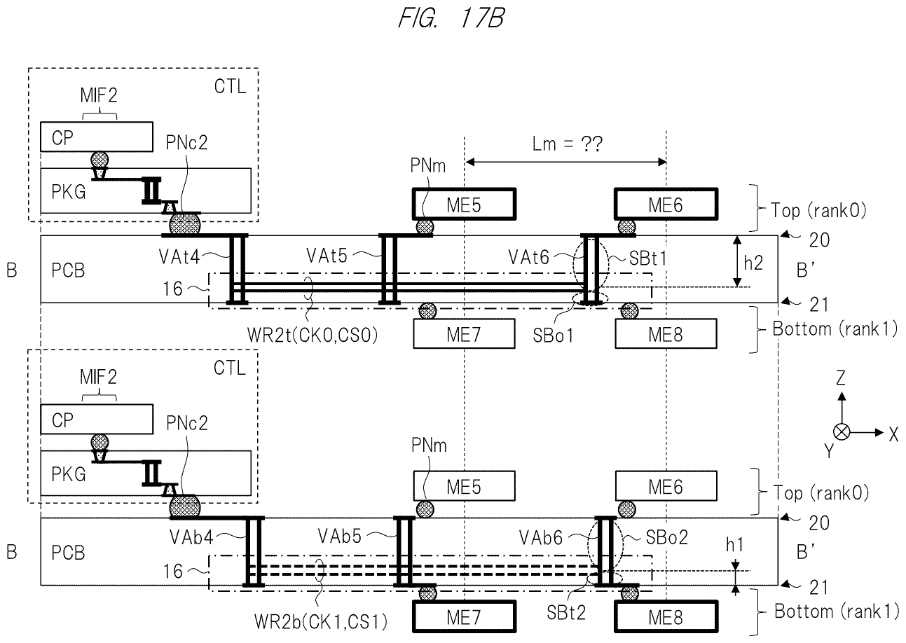

FIG. 17A is a cross-sectional view illustrating an exemplary configuration of an electronic device in a comparative example, which is different from that of FIG. 4A. FIG. 17B is a cross-sectional view illustrating an exemplary configuration of the electronic device in the comparative example, which is different from that of FIG. 4B. FIGS. 17A and 17B illustrate exemplary configurations based on typical thoughts. For example, when a wiring is drawn from the control device CTL mounted on the front surface 20 of the wiring substrate PCB, typically, a wiring drawn from an end of the control device CTL is allocated to a wiring layer closer to the front surface while a wiring drawn from the inside of the control device CTL is allocated to a wiring layer closer to the back surface. Thereby, the wirings can be configured so that the wiring drawn from the end of the control device CTL does not inhibit the wiring drawn from the inside thereof.

On the basis of the thoughts, when the memory interfaces MIF1 and MIF2 are arranged as illustrated in FIG. 2, the wirings WR1 drawn from the memory interface MIF1 at the end of the device are allocated to the wiring layer closer to the front surface. To the contrary, the wirings WR2 drawn from the memory interface MIF2 arranged inside the device are allocated to the wiring layer closer to the back surface. That is, the wiring layers to be allocated are defined by the positions of the memory interfaces MIF1 and MIF2.

Accordingly, in the example of FIG. 17A, both the wirings WR1t and the wirings WR1b are allocated to a wiring layer 15 closer to the front surface. As similar to the case of FIG. 4A, through the wirings WR1t, the clock signal CK0 and the chip select signal CS0 propagate from the memory interface MIF1 to the memory devices ME1 and ME2 of rank 0. Through the wirings WR1b, the clock signal CK1 and the chip select signal CS1 propagate from the memory interface MIF1 to the memory devices ME3 and ME4 of rank 1.

To the contrary, in the example of FIG. 17B, both the wirings WR2t and the wirings WR2b are allocated to a wiring layer 16 closer to the back surface. As similar to the case of FIG. 4B, through the wirings WR2t, the clock signal CK0 and the chip select signal CS0 propagate from the memory interface MIF2 to the memory devices ME5 and ME6 of rank 0. Through the wirings WR2b, the clock signal CK1 and the chip select signal CS1 propagate from the memory interface MIF2 to the memory devices ME7 and ME8 of rank 1.

When attention is paid to, for example, the signal paths of the chip select signals CS0 and CS1 in FIG. 17A, the lengths of the through via wirings VA along the signal paths are different between the access to rank 0 and the access to rank 1 Specifically, the through via wiring VAt3 for the connection to the memory device ME2 of rank 0 includes a via section SBt1 for signal propagation and an open stub SBo1.

The via section SBt1 for signal propagation is a via section for propagating a signal to a target memory device ME. The via section SBt1 for signal propagation is made of a section between the connecting point with the wirings WR1t and the front surface 20 of the wiring substrate PCB. Meanwhile, the open stub SBo1 is a stub having an open end. The open stub SBo1 described here is made of a section between the connecting point with the wirings WR1t and the back surface 21 of the wiring substrate PCB.

Similarly, the through via wiring VAb3 for the connection to the memory device ME4 of rank 1 also includes a via section SBt2 for signal propagation and an open stub SBo2. In contrast to the through via wiring VAt3, the via section SBt2 for signal propagation is made of a section between the connecting point with the wirings WR1b and the back surface 21 of the wiring substrate PCB. To the contrary, the open stub SBo2 is made of a section between the connecting point with the wirings WR1b and the front surface 20 of the wiring substrate PCB.

In the access to rank 0, the length of the via section SBt1 for signal propagation is “h1.” To the contrary, In the access to rank 1, the length of the via section SBt2 for signal propagation is “h2” longer than “h1.” In other words, while the length of the open stub SBo1 is “h2,” the length of the open stub SBo2 is “h1” less than “h2.”

Also in FIG. 17B, as similar to the case of FIG. 17A, the lengths of the through via wirings VA along the signal paths are different between the access to rank 0 and the access to rank 1. That is, the length of the via section SBt1 for signal propagation in the through via wiring VAt6 for the access to rank 0 is “h2.” To the contrary, the length of the via section SBt2 for signal propagation in the through via wiring VAb6 for the access to rank 1 is “h1” less than “h2.” The description has been made in the exemplary signal paths of the chip select signals CS0 and CS1 here. However, the same goes for the signal paths of the clock signals CK0 and CK1.

As described above, if the lengths of the through via wirings VA along the signal paths are different between the access to rank 0 and the access to rank 1, the waveforms of the reflected signal as illustrated in FIGS. 15A and 15B are different between the access to rank 0 and the access to rank 1. Thereby, the signals, which reach the memory devices ME on the front and back surfaces, are asymmetric to each other. This may result in the decrease in operation margin at the time of the access to the memory device ME. This is because the entire operation margin is defined based on the worse waveform integrity. The decrease in operation margin may result in an error at the time of the access to the memory device ME.

The chip select signals CS are particularly important for the switching between rank 0 and rank 1, and thus, the operation margin is desirably increased by improving the waveform integrity such as signal symmetry. This desirably results in bringing the error at the time of the access to the memory device ME to zero. Further, the clock signals CK are also important for determining the signal timing, and thus, it is desirable to improve the waveform integrity such as signal symmetry.

### Detail of Electronic Device (Embodiment)

It is beneficial to use the exemplary configurations of FIGS. 4A and 4B. The exemplary configurations of FIGS. 4A and 4B are different from the exemplary configurations of FIGS. 17A and 17B in the following two points. The first difference is that the wirings WR1t, WR1b, WR2t, and WR2b for propagating the clock signals CK and the chip select signals CS in FIGS. 4A and 4B are allocated to the wiring layers by a different method from that of FIGS. 17A and 17B. The second difference is that a distance between two memory devices ME, which are adjacent to each other, in FIGS. 4A and 4B is determined to a predetermined value for each rank.

### <<Method for Allocation to Wiring Layer>>

For the first difference, in the exemplary configuration of FIG. 4A, the wirings WR1t from the memory interface MIF1 to the memory devices ME1 and ME2 of rank 0 are provided in the wiring layer 15 closer to the front surface of the wiring layers, in other words, the wiring layer closer to the front surface 20 than the back surface 21. To the contrary, the wirings WR1b from the memory interface MIF1 to the memory devices ME3 and ME4 of rank 1 are provided in the wiring layer 16 closer to the back surface of the wiring layers, in other words, the wiring layer closer to the back surface 21 than the front surface 20.

As similar to the exemplary configuration of FIG. 4B, the wirings WR2t from the memory interface MIF2 to the memory devices ME5 and ME6 of rank 0 are provided in the wiring layer 15 closer to the front surface. To the contrary, the wirings WR2b from the memory interface MIF2 to the memory devices ME7 and ME8 of rank 1 are provided in the wiring layer 16 closer to the back surface. In this way, in FIGS. 4A and 4B, the wiring layers are determined based on the arrangement of not the memory interfaces MIF1 and MIF2 but the memory devices ME, in other words, based on the rank, as different from FIGS. 17A and 17B.

Along with the configuration, the length “h1” of the via section SBt1, SBt2 for signal propagation in the through via wiring VAt3, VAb3 illustrated in FIG. 4A is less than the length “h2” of the open stub SBo1, SBo2. Similarly, the length “h1” of the via section SBt1, SBt2 for signal propagation in the through via wiring VAt6, VAb6 illustrated in FIG. 4B is less than the length “h2” of the open stub SBo1, SBo2.

That is, in FIGS. 4A and 4B, the via sections SBt1 and SBt2 for signal propagation are configured to be short, irrespective of whether to the access to rank 0 or rank 1. In the present specification, the via sections SBt1 and SBt2 for signal propagation are collectively called via section SBt for signal propagation. The open stubs SBo1 and SBo2 are collectively called open stub SBo.

The effects provided by the configuration are the decrease in load capacity in the via section SBt for signal propagation, and consequently the decrease in reflected signals and the improvement in integrity of transmitting signals. The clock signals CK and the chip select signals CS are propagated only to the memory device ME mounted on either the front surface 20 or the back surface 21. Thus, each of the through via wirings VA for propagating the signals absolutely includes the open stub SBo.

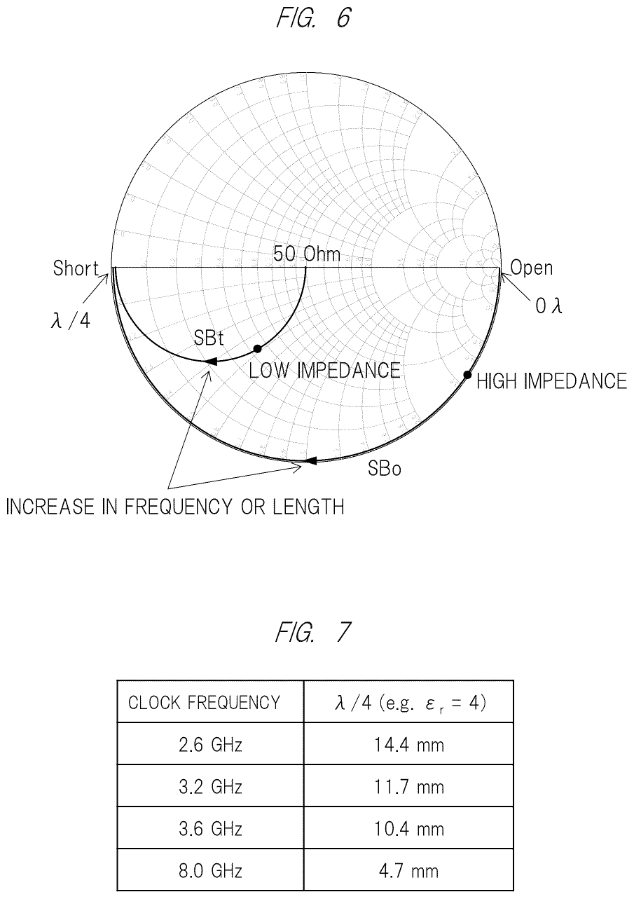

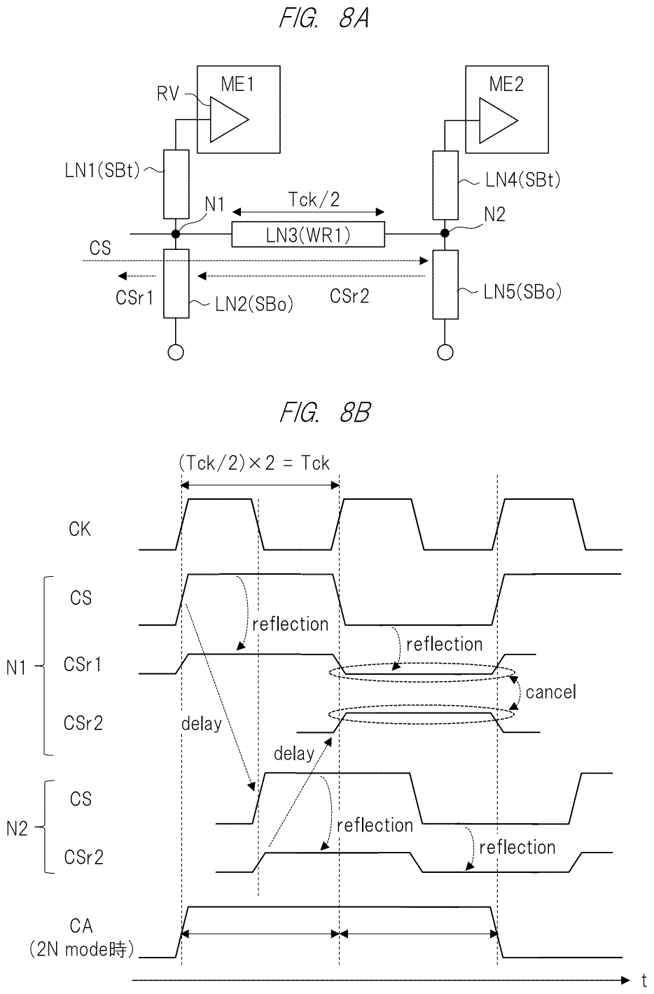

FIG. 6 is an impedance chart illustrating an exemplary impedance property of the via section SBt for signal propagation and the open stub SBo in FIGS. 4A and 4B. As illustrated in the impedance chart that is a Smith chart in FIG. 6, the impedance of the open stub SBo is infinite at a length of zero, or zero at a length of a quarter of the wavelength λ of the propagation signal. The larger the length of the open stub SBo is, or the larger the frequency of the propagation signal is, the larger a range of the clockwise rotation of the feature point on the outer periphery of the chart is. The impedance accordingly decreases.

To the contrary, for example, when it is assumed that an input terminal of the memory device ME is terminated at 50Ω by on die termination (ODT), the impedance of the via section SBt for signal propagation is 50Ω at the length of zero. To the contrary, if the via section SBt for signal propagation has a finite length, the input capacitance of the memory device ME and the coupling capacitance with the wiring substrate PCB function as parallel-connection capacitance, and functions as a kind of short stub. The coupling capacitance is increased by increase in the length of the via section SBt for signal propagation. Therefore, the feature point of the via section SBt for signal propagation is rotated clockwise on the equi-conductance circle from the point of 50Ω by the increase in the length of the via section SBt or the increase in the frequency of the propagation signal. The impedance accordingly decreases.

In consideration of such a property, when the length of the open stub SBo is sufficiently less than λ/4, the relationship of expression (1) is established per unit length of the through via wiring VA. To the contrary, when the length of the open stub SBo is made close to λ/4 by the increase in the frequency of the propagation signal, the open stub SBo is converted into the short stub and rapidly has a large capacity. Consequently, the relationship of expression (1) is inverted into that of expression (2).

$$Capacitive load of SBo < Capacitive load of SBt \qquad ( 1 )$$

$$Capacitive load of SBo > Capacitive load of SBt \qquad ( 2 )$$

The conflicting expressions (1) and (2) mean that, when the length of the open stub SBo is sufficiently less than λ/4, the signal reflection can be made less in the case of the longer open stub SBo and the shorter via section SBt for signal propagation, thereby improving the signal transmitting property. That is, as can be seen from FIG. 6, when the length of the open stub SBo is sufficiently less than λ/4, the impedance of the open stub SBo is sufficiently higher than that of the via section SBt for signal propagation. Thus, the reflection property at the branch point is dominantly defined by the capacitance property of the via section SBt for signal propagation. When the via section SBt for signal propagation is shortened, the impedance can be made closer to 50Ω, thereby decreasing the reflected signal.

In this way, it is important to shorten the length of the open stub SBo to be at least less than λ/4 in consideration of λ/4. FIG. 7 is a diagram illustrating exemplary results of calculation for how much a quarter length of the wavelength λ of the propagation signal depends on a Nyquist frequency. The calculation results are shown in assumption that the relative permittivity εᵣ of a dielectric material making the wiring substrate PCB is 4.0. Note that the Nyquist frequency is equal to the clock frequency in DDR5_SDRAM. The quarter length of the wavelength λ at the highest Nyquist frequency that is 3.6 GHZ applicable to DDR5_SDRAM is, for example, about 10.4 mm.

To the contrary, the thickness of the wiring substrate PCB is typically about 1.0 to 4.0 mm. Thus, the length of the open stub SBo at the Nyquist frequency of 3.6 GHz is sufficiently less than λ/4, that is, 10.4 mm. The quarter length of the wavelength λ at a Nyquist frequency of 8.0 GHz is 4.7 mm. Even in this case, the length of the open stub SBo is less than λ/4, that is, 4.7 mm. That is, unless the extremely thick wiring substrate PCB is used, it can be said that the expression (1) is established until it exceeds nearly a signal propagation speed of about 16 Gbps.

Therefore, it is beneficial to shorten the length of the via section SBt for signal propagation as illustrated in FIGS. 4A and 4B particularly in the electronic device 10 mounting the memory devices ME such as DDR5 SDRAM thereon. Thereby, the total load capacity of the through via wirings VA is minimized, the reflected signals decrease, and the transmitting signals increase. Consequently, the waveform integrity can be improved.

Distance between Memory Devices

For the second difference, in the exemplary configuration of FIG. 4A, a distance Lm between the memory device ME1 and the memory device ME2 of rank 0 is defined on the basis of a propagation delay time given by expression (3). That is, the distance Lm is defined on the basis of the wiring length of the wiring WR1 corresponding to the propagation delay time given by expression (3). A term “Tck” in expression (3) is a cycle of the clock signal CK. The distance Lm between the memory device ME3 and the memory device ME4 of rank 1 is also defined on the basis of the propagation delay time given by expression (3). The exemplary configuration of FIG. 4B is also similar to that of FIG. 4A.

$$Lm = Tck / 2 \qquad ( 3 )$$

More preferably, the distance Lm between the two memory devices ME, which are adjacent to each other, is defined on the basis of the propagation delay time given by expression (4). A term “τᵥₐ” in expression (4) is propagation delay time of the via section SBt for signal propagation, and is given by expression (5). A term “εᵣ” in expression (5) is the relative permittivity of the dielectric material making the wiring substrate PCB. A term “c₀” is a speed of light in vacuum. Note that the distance Lm between two memory devices ME is also a distance between two through via wirings VA through which the same signal propagates, such as a distance between the through via wiring VAt2 and the through via wiring VAt3 in FIG. 4A.

$$Lm = Tck / 2 - {τ}_{v a} \qquad ( 4 )$$

$${τ}_{v a} = ( Length of SBt ) \times √ ( {ε}_{r} ) / {c}_{0} \qquad ( 5 )$$

By the application of such a distance, the reflected signals can be canceled as described below. In practice, however, it is not easy to completely cancel the reflected signals. Thus, it is beneficial to also use the allocation method to the wiring layers. That is, it is desirable to previously decrease the reflected signals by the allocation method to the wiring layers.

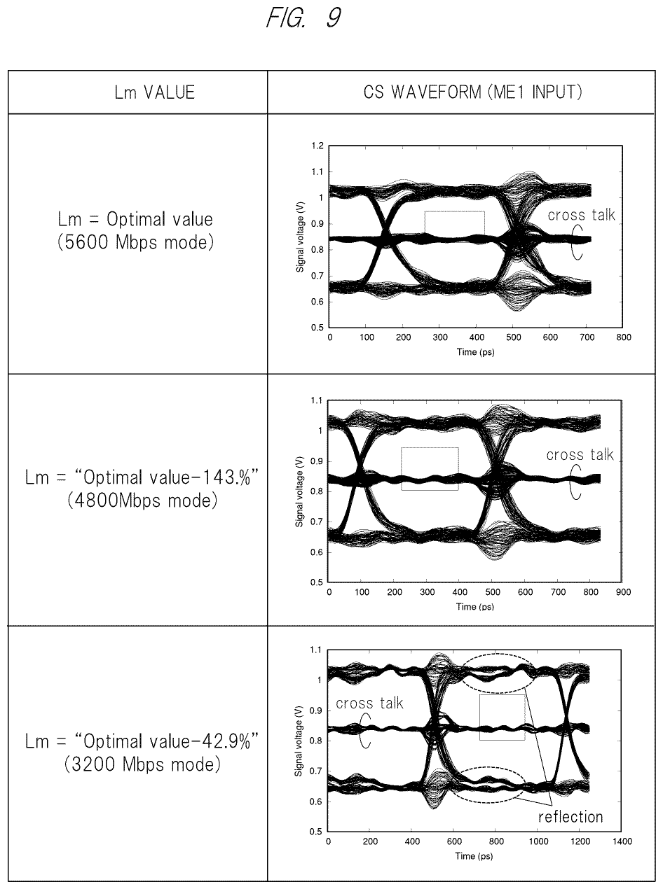

FIG. 8A is a circuit diagram illustrating an exemplary equivalent configuration for signal propagation paths to rank 0 in FIG. 4A. FIG. 8B is a timing chart conceptually illustrating a mechanism of cancelling the reflected signals in FIG. 8A. In FIG. 8A, a transmission line LN3 corresponding to the wirings WR1 for propagating the chip select signal CS is provided between the two memory devices ME1 and ME2. The propagation delay time of the transmission line LN3 is defined by expression (3).

A branch node N1 at one end of the transmission line LN3 is connected to a receiver RV of the memory device ME1 through a transmission line LN1 corresponding to the via section SBt for signal propagation. Further, the branch node N1 leads to an open end through a transmission line LN2 corresponding to the open stub SBo. Similarly, a branch node N2 at the other end of the transmission line LN3 is connected to a receiver RV of the memory device ME2 through a transmission line LN4 corresponding to the via section SBt for signal propagation. Further, the branch node N2 leads to an open end through a transmission line LN5 corresponding to the open stub SBo.

FIG. 8B illustrates the clock signal CK, the chip select signal CS and reflected signals CSr1, CSr2 at the branch node N1, and the chip select signal CS and the reflected signal CSr2 at the branch node N2. The clock signal CK and the chip select signal CS are signals output from the control device CTL not illustrated. The reflected signal CSr1 is a reflected signal of the chip select signal CS, reflected on the branch node N1. The reflected signal CSr2 is a reflected signal of the chip select signal CS, reflected on the branch node N2. In this example, it is assumed that the phase components of the reflection coefficients at the branch nodes N1 and N2 are zero for simple explanation.

In FIG. 8B, the reflected signal CSr1 with the same phase as the chip select signal CS is caused at the branch node N1. To the contrary, the chip select signal CS passing through the branch node N1 is delayed by “Tck/2” and reaches the branch node N2. Accordingly, the reflected signal CSr2 is caused also at the branch node N2 as similar to the case of the branch node N1. The reflected signal CSr2 is delayed by “Tck/2” and returns to the branch node N1.

Once the reflected signal CSr2 reaches the branch node N1, the reflected signal CSr1 with the different polarity from the previous one is caused at the branch node N1. The reflected signal CSr1 with the different polarity and the reflected signal CSr2 output from the branch node N2 cancel each other at the branch node N1. Actually, the reflection coefficients at the branch nodes N1 and N2 have a phase component, that is, a reactance component. Thus, the reflected signal is mainly caused at the rise/fall period of the chip select signal CS, and has a different phase from the chip select signal CS. Even in this case, as long as the magnitude and the phase of the reflection coefficient are the same between the two branch nodes N1 and N2, the mechanism similar to that of FIG. 8B is established.

As described above, when expression (3) is met, the reflection of the chip select signal CS operating in the single data rate (SDR) mode can be canceled at the branch node N1. The SDR mode is an operating mode in which the cycle Tck of the clock signal CK is regarded as one data unit. Thereby, the waveform integrity can be improved particularly in the memory device ME1 arranged at the branch closer to the control device CTL as illustrated in FIGS. 15A and 15B.

When the signal is reflected on the through via wiring VA, strictly speaking, the reflection with zero delay is not caused at the connecting point between the wirings and the through via wiring VA, and the reflection is caused such that the signal returns to the original direction after entering the through via wiring VA to some extent. Therefore, more strictly speaking, it is necessary to determine the propagation delay time between two memory devices ME in consideration of the intrusion delay at this time. The intrusion delay is reflected on the propagation delay time τᵥₐ in expression (4) and expression (5).

Roundtrip delay time in the through via wiring VA can be approximated to typical relaxation time given by expression (6) taking “e” as the base of natural logarithm. The delay time per unit length in the through via wiring VA is generally longer than the delay time of the wiring, and is almost 1.3 to 1.4 times longer than the delay time of the wiring although, strictly speaking, depending on the layout. Thus, replacement with ordinary signal delay in expression (6) provides expression (7).

$$( Through via delay ) \times ( 1 / e ) \times 2 \qquad ( 6 )$$

$$( Ordinary signal delay ) \times ( 1.3 to 1.4 ) \times ( 2 / e ) = ( Ordinary signal delay ) \times ( 0.96 to 1.03 ) \qquad ( 7 )$$

As described above, the roundtrip delay time in the through via wiring VA is almost equal to the one-way delay time in the ordinary signal wiring. By reflection of the result, expression (4) and expression (5) are provided. If a wiring layer changes, the magnitude of the intrusion delay changes, and thus, the degree of the effect of cancelling the reflected signal slightly changes. As described later, however, the propagation delay time for defining the distance Lm has a certain margin, such as 14%, for the delay change. Thus, a large problem is particularly not caused. Due to such margin, the distance Lm given by not expression (4) but expression (3) may be applied.

### <Clock Signal>

By application of the distance Lm between the memory devices ME and/or application of the allocation method to the wiring layers, the waveform integrity such as the waveform symmetry of the clock signals CK as illustrated in FIG. 16 can be improved. Specifically, when expression (3) or expression (4) is established, the roundtrip delay time of the clock signal CK between the memory devices ME is equal to the cycle of the clock signal CK. Thus, for example, almost equal amounts of reflected signals are combined at a constant timing in the memory devices ME1 and ME2 of rank 0 illustrated in FIG. 4A.

Consequently, the clock signals CK with symmetric waveforms can be input into the memory devices ME1 and ME2 to which the fly-by system is applied. Further, for example, the allocation method to the wiring layers is also applied to the memory device ME1 and the memory device ME3 on the front surface 20 and the back surface 21 to which the Clamshell is applied in FIG. 4A, thereby equalizing the reflection coefficients at the branch nodes corresponding to the respective memory devices ME. Therefore, the clock signals CK with almost the same waveforms can be input into the memory devices ME1 and ME3.

In this regard, for example, the length of the via section SBt1 for signal propagation for propagating the clock signal CK0 is to be equal to the length of the via section SBt2 for signal propagation for propagating the clock signal CK1 in FIG. 4A. The same goes to the chip select signals CS. Therefore, the length of the via section SBt1 for signal propagation for propagating the chip select signal CS0 is to be equal to the length of the via section SBt2 for signal propagation for propagating the chip select signal CS1. That is, the wirings WR1t and WR1b for propagating the same kind of signals may be arranged to be symmetric to each other with respect to the intermediate wiring layer in the wiring substrate PCB.

### <Command Address Signal>

As illustrated in FIG. 5 and the like, the wirings WR1tb for propagating the command address signals CA are commonly connected to the memory devices ME1 and ME3 on the front surface 20 and the back surface 21. This does not result in the effect of decreasing the capacity in the through via wirings VA, that is, the effect provided by the allocation method to the wiring layers. However, this results in the effect of cancelling the reflected signals, that is, the effect provided by the distance Lm between the memory devices ME.

For example, a “2N mode” is supported for the command address signals CA in DDR5_SDRAM. The 2N mode is an operation mode in which two cycles “2×Tck” of the clock signal CK is taken as one unit as illustrated in FIG. 8B. In the 2N mode, the effect of cancelling the reflected signals is slightly different from that in the chip select signals CSm operating in the SDR mode. That is, in the 2N mode, for every two round-trip propagations of the command address signal CA between two memory devices ME, the reflected signals are reversed in phase.

In the example of FIG. 8B, note that the reflected signal CSr2 caused at the first cycle of the clock signal CK and the reflected signal CSr1 caused at the third cycle of the clock signal CK are canceled in response to the command address signal CA. Thereby, as long as the reflection continues, for every even number of times of round-trip propagations of the command address signal CA, such as two round-trip propagations, four round-trip propagations, six round-trip propagations, . . . , the phase-revered reflected signals are mutually canceled. An odd number of times of the round-trip propagations does not cause the cancelation, and thus, the effect of cancelling the reflected signals is almost half of that of the chip select signals CS.

The margin for errors in the command address signals CA is larger than those of the chip select signals CS and the clock signals CK. Further, since the timing margin or the like is increased by the using the 2N mode, the errors are less likely to occur. Therefore, the required waveform integrity of the address signals CA can be sufficiently achieved command particularly by using the 2N mode.

### <Simulation Result>

FIG. 9 is a waveform diagram illustrating exemplary simulation results targeting the memory device ME1 closer to the control device in FIG. 4A and resulted from observation of input waveforms of the chip select signal CS. In assumption here that a signal propagation speed is 5600 Mbps, the distance Lm between the two memory devices ME1 and ME2 is determined based on expression (4), and is defined as an optimum value. While the distance Lm between the memory devices ME1 and ME2 is kept, the signal propagation speed is changed to 4800 Mbps and 3200 Mbps.

Accordingly, at the signal propagation speed of 4800 Mbps, the distance Lm between the memory devices ME1 and ME2 was about 14.3% shorter than the optimum value. Similarly, at the signal propagation speed of 3200 Mbps, the distance Lm between the memory devices ME1 and ME2 was about 42.9% shorter than the optimum value.

In FIG. 9, at 5600 Mbps and 4800 Mbps, the reflected signals were almost removed, and the excellent waveforms of the chip select signal CS, that is, eye pattern was provided. To the contrary, at 3200 Mbps, the reflected signals were not canceled and clearly observed. However, because of the use of the allocation method to the wiring layers, the magnitudes of the reflected signals were small. From the simulation results, it has been found that the excellent effect can be provided even if the distance Lm between the memory devices ME1 and ME2 shifts by about 14%. If the optimum value of the distance Lm is defined based on a certain signal propagation speed as described above, this effect may be made small when the signal propagation speed decreases.

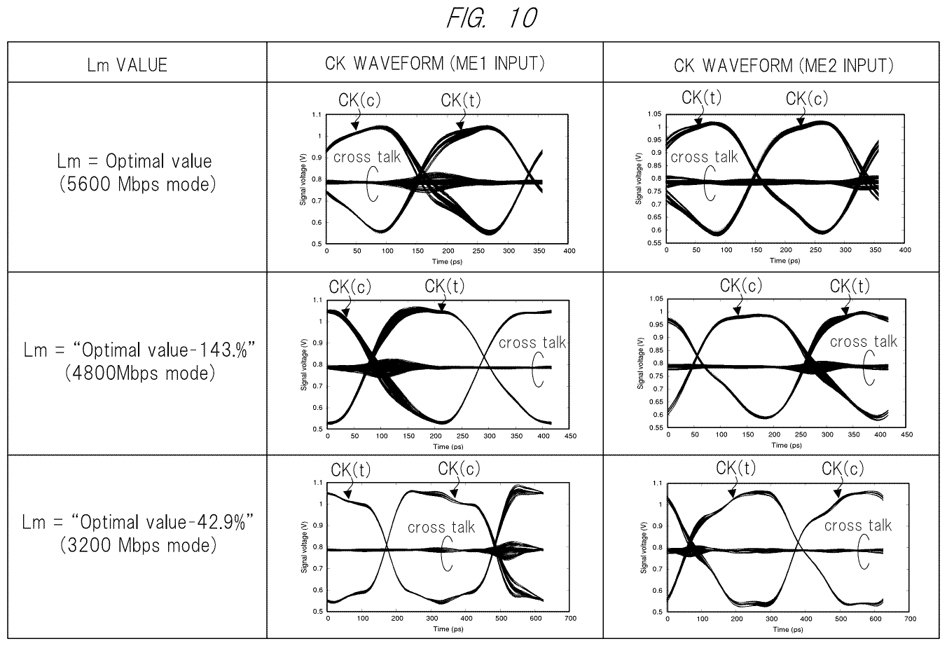

FIG. 10 is a waveform diagram illustrating exemplary simulation results targeting the memory device ME closer to and the memory device ME2 farther from the control device CTL in FIG. 4A and resulted from observation of input waveforms of the clock signal CK. The evaluation index in this case is the waveform symmetry as also described in FIG. 16.

At the signal propagation speed of 5600 Mbps, the sufficiently symmetric waveforms were provided in the relation between the clock signal CK into the memory device ME1 and the clock signal CK into the memory device ME2. That is, the waveforms of the negative-polarity clock signal CK(c) and the positive-polarity clock signal CK(t) into the memory device ME1 were equal to the waveforms of the positive-polarity clock signal CK(t) and the negative-polarity clock signal CK(c) into the memory device ME2.

Even at the signal propagation speed of 4800 Mbps, the substantially symmetric waveforms were provided. To the contrary, at the signal propagation speed of 3200 Mbps, the waveforms were asymmetric. From the simulation results, it has been found that the margin for the distance Lm between two memory devices ME is about 14% as similar to that of the chip select signals CS.

### <Detailed Cross-sectional Configuration of Electronic Device (Embodiment)>

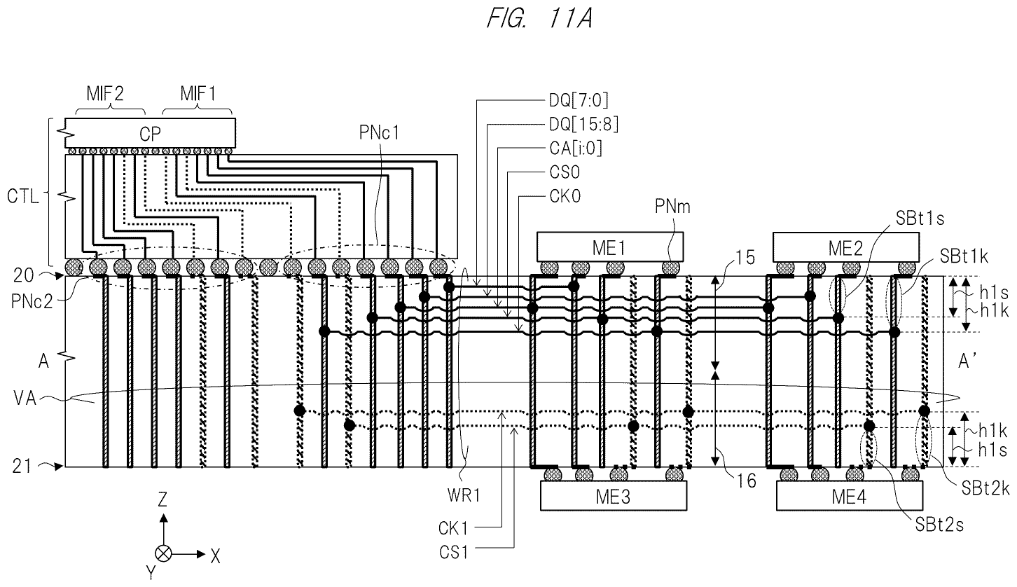

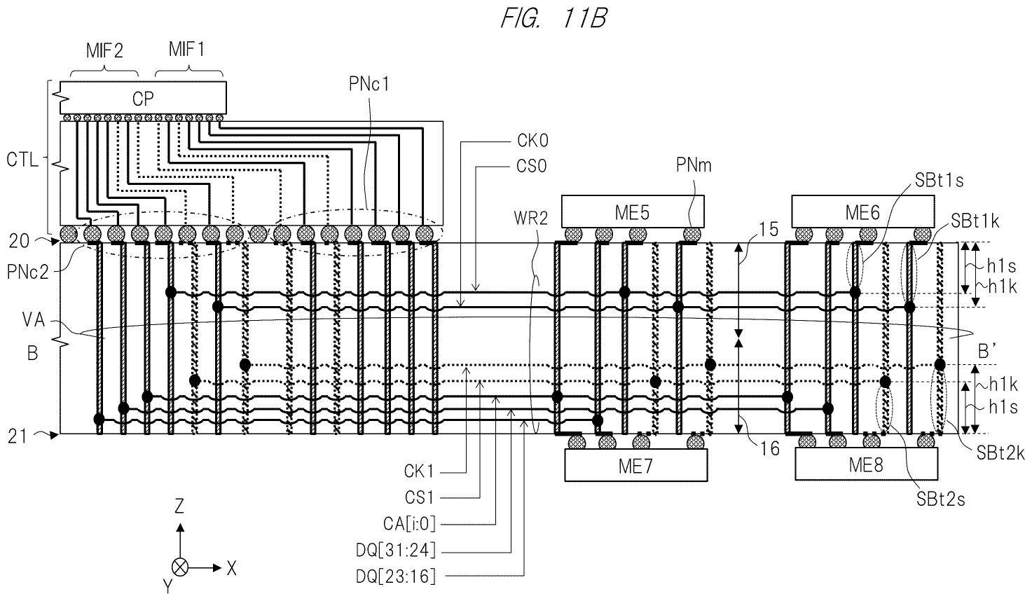

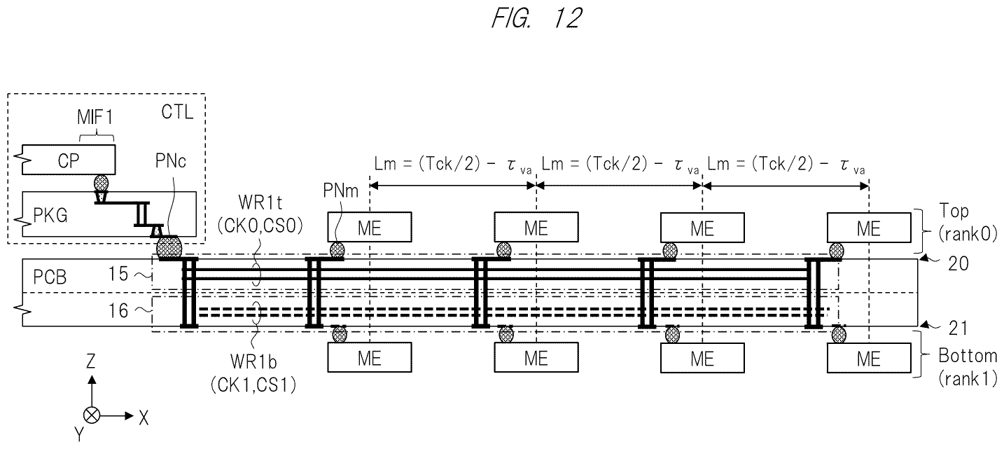

FIG. 11A is a cross-sectional view illustrating a detailed exemplary configuration along the line A-A′ of FIG. 2. As illustrated in FIG. 4A, FIG. 11A shows that the wiring WR1 for propagating the chip select signal CS0 toward the front surface 20 and the wiring WR1 for propagating the clock signal CK0 toward the front surface 20 are provided in the wiring layer 15 closer to the front surface 20. To the contrary, the wiring WR1 for propagating the chip select signal CS1 toward the back surface 21 and the wiring WR1 for propagating the clock signal CK1 toward the back surface 21 are provided in the wiring layer 16 closer to the back surface 21. The external terminal PNc2 of the memory interface MIF2 is closer to the inside of the control device CTL than the external terminal PNc1 of the memory interface MIF1.

In this case, for example, both a length of a via section SBt1k for signal propagation for propagating the clock signal CK0 toward the front surface 20 and a length of a via section SBt2k for signal propagation for propagating the clock signal CK1 toward the back surface 21 have the same value “h1k.” Similarly, both a length of a via section SBt1s for signal propagation for propagating the chip select signal CS0 toward the front surface 20 and a length of a via section SBt2s for signal propagation for propagating the chip select signal CS1 toward the back surface 21 have the same value “h1s.”

The wiring WR1 through which the command address signal CA[i:0] propagates is connected to all the memory devices ME1 to ME4 mounted on the front surface 20 and the back surface 21 in a “wired OR” form. Single wiring WR1 is illustrated here. However, specifically, “i+1” wirings WR1 are provided. The “i +1” wirings WR1 may be distributed in the wiring layers as appropriate.

In this example, eight wirings WR1 through which an 8-bit data signal DQ[7:0] propagates to one of the two memory devices ME1 and ME3 and eight wirings WR1 through which an 8-bit data signal DQ[15:8] propagates to one of the two memory devices ME2 and ME4 are provided. A total of 16 wirings WR1 through which a data signal DQ[15:0] propagates may be also distributed in the wiring layers as appropriate.

FIG. 11B is a cross-sectional view illustrating a detailed exemplary configuration along the line B-B′ of FIG. 2. As illustrated in FIG. 4B, the wiring WR2 through which the chip select signal CS0 propagates toward the front surface 20 and the wiring WR2 through which the clock signal CK0 propagates toward the front surface 20 are provided in the wiring layer 15 closer to the front surface 20 in FIG. 11B. To the contrary, the wiring WR2 through which the chip select signal CS1 propagates toward the back surface 21 and the wiring WR2 through which the clock signal CK1 propagates toward the back surface 21 are provided in the wiring layer 16 closer to the back surface 21. As illustrated in FIG. 4B, FIG. 11B shows that the wiring WR2 through which the chip select signal CS0 propagates toward the front surface 20 and the wiring WR2 through which the clock signal CK0 propagates toward the front surface 20 are provided in the wiring layer 15 closer to the front surface 20. To the contrary, the wiring WR2 through which the chip select signal CS1 propagates toward the back surface 21 and the wiring WR2 through which the clock signal CK1 propagates toward the back surface 21 are provided in the wiring layer 16 closer to the back surface 21. The lengths of the via sections for signal propagation are similar to those in FIG. 11A.

As similar to FIG. 11A, the “i+1” wirings WR2 through which the command address signal CA[i:0] propagates may be also distributed in the wiring layers as appropriate. In this example, eight wirings WR2 through which an 8-bit data signal DQ[23:16] propagates to one of the two memory devices ME5 and ME7 and eight wirings WR2 through which an 8-bit data signal DQ[31:24] propagates to one of the two memory devices ME6 and ME8 are provided. A total of 16 wirings WR2 through which a data signal DQ[31:16] propagates may be also distributed in the wiring layers as appropriate.

### Modification Example

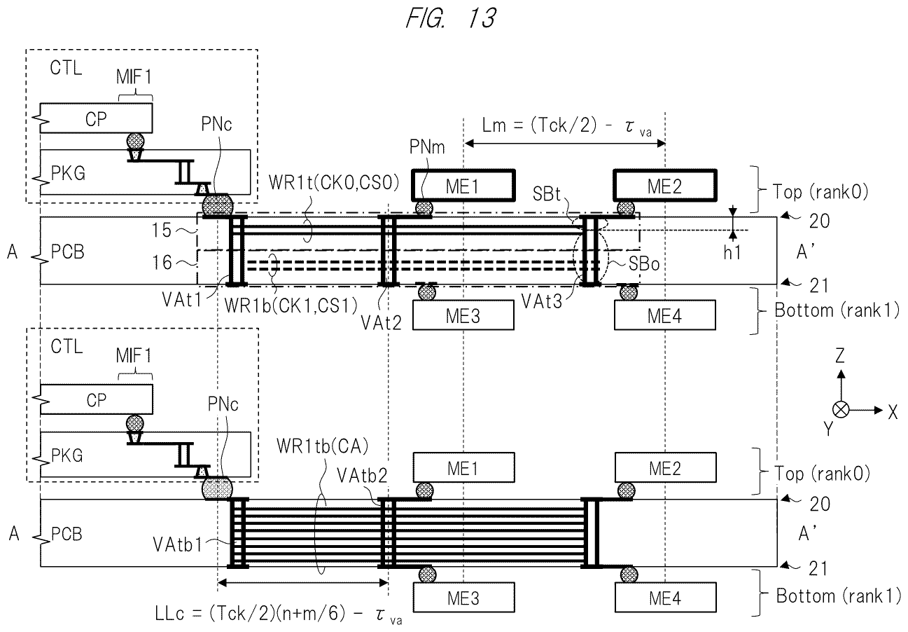

FIG. 12 is a cross-sectional view illustrating an expanded exemplary configuration of the configuration of FIG. 4A. In FIG. 12, even-number memory devices, here four memory devices ME including the memory devices ME1 and ME2 of FIG. 4A are mounted on the front surface 20 of the wiring substrate PCB. The even-number memory devices ME configure rank 0, and are accessed by using the common clock signal CK0 and the common chip select signal CS0.

Similarly, even-number memory devices, here four memory devices ME including the memory devices ME3 and ME4 of FIG. 4A are mounted on the back surface 21 of the wiring substrate PCB. The even-number memory devices ME configure rank 1 and are accessed by using the common clock signal CK1 and the common chip select signal CS1.

The distance Lm between two memory devices ME, which are adjacent to each other, of the even-number memory devices ME mounted on the front surface 20 is defined based on the propagation delay time given by expression (3) or expression (4). Similarly, the distance Lm between two memory devices ME, which are adjacent to each other, of the even-number memory devices ME mounted on the back surface 21 is also defined based on the propagation delay time given by expression (3) or expression (4).

When the fly-by system is used as described above, the number of branches can be increased to two or more. In this case, the memory devices ME, which are adjacent to each other, may be arranged at an equal interval as illustrated in FIG. 12. However, the number of memory devices ME mounted on each surface needs to be an even number. If the odd-number memory devices ME are mounted, the reflected signals may be mutually strengthened in some combinations of the memory devices ME. Note that the bit widths of the data signals DO in the memory interfaces MIF1 and MIF2 are generally extended in one unit of 2ⁿ. Thus, even in this regard, the number of memory devices ME mounted on each surface may be generally an even number.

### Principal Effect of First Embodiment

As described above, in the first embodiment, the method for allocating the wirings through which the chip select signals and the clock signals propagate to the wiring layers and the distance between the memory devices, which are adjacent to each other, are mainly defined. The electronic device according to the first embodiment adopts at least one of, or preferably both the two technical elements. Thereby, the waveform integrity of the chip select signals and the clock signals are typically improved. Further, the waveform integrity can be improved without providing the resistor device as described in the Patent document 1. Consequently, the electronic device can be downsized.

### Second Embodiment

### <Schematic Cross-sectional Configuration of Electronic Device>

FIG. 13 is a cross-sectional view illustrating an exemplary schematic configuration for clock signals, chip select signals and command address signals along the line A-A′ of FIG. 2 in an electronic device according to a second embodiment. FIG. 13 illustrates a similar configuration to that of FIGS. 4A and 5. FIG. 13 is different from FIGS. 4A and 5 in that a wiring length LLC between the external terminal PNC for outputting a predetermined control signal from the control device CTL and through via wiring Vat2, VAtb2 for propagating the predetermined control signal to the memory device ME1, ME3 closer to the control device CTL is defined to a predetermined value.

Specifically, the wiring length LLC is defined based on propagation delay time given by expression (8). That is, the wiring length LLc indicates the wiring length of the wiring WR1t, WR1b, WR1tb corresponding to the propagation delay time. A term “Tck” in expression (8) is a cycle of the clock signal CK. Terms “n” and “m” are integers other than negative integers. A term “τᵥₐ” is propagation delay time of the via section SBt for signal propagation described in expression (5). Note that the term “τᵥₐ” in expression (8) may be zero as similar to that in the relationship between expression (3) and expression (4).

$$LLc = ( Tck / 2 ) ( n + m / 6 ) - {τ}_{v a} \qquad ( 8 )$$

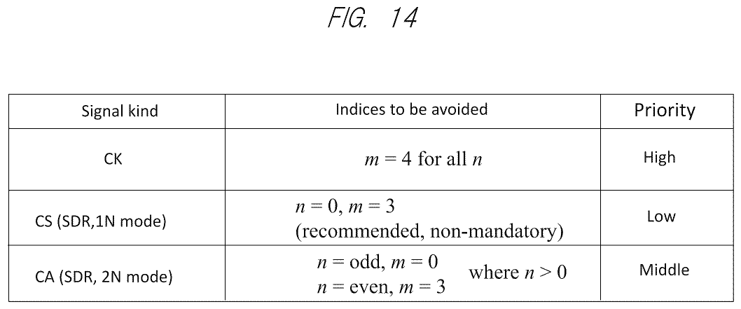

FIG. 14 is a table illustrating combinations with “n” and “m” to be avoided, for the wiring length LLC between the control device CTL and the memory device ME1 of FIG. 13. In FIG. 14, the priority is set in descending order of influence on the waveform integrity. In FIG. 14, the command address signals CA are assumed in the 2N operation mode, and limitations in the 2N mode are illustrated. If the command address signals CA operate in the SDR mode, the rule for the chip select signals CS is to be followed.

The reflected signals may specifically affect not only between the memory devices ME, which are adjacent to each other, in the first embodiment but also between the control device CTL and the memory devices ME. That is, the through via wirings VAt1 and VAtb1 are also present closer to the control device CTL, and thus, the reflected signals from the through via wirings VAt1 and VAtb1 affect the effect of cancelling the reflected signals described in the first embodiment.

At this time, the reflected signals from the through via wirings VAt1 and VAtb1 closer to the control device CTL are caused because of the reaching of the signals which are not canceled between the memory devices ME but remain. Thus, the signals other than the clock signals CK are less affected. In consideration of this regard, the priorities of the signals other than the clock signals CK are set lower in FIG. 14.

In this case, even if there is no branch to the memory devices ME, the waveform integrity of the clock signals CK may be affected by the wiring length, more accurately, by the remainder obtained by dividing the delay by half the clock cycle. Thus, the present inventors have examined the influence of wiring delay under simulations taking ⅙ of half the cycle “Tck/2” of the clock signal CK as a resolution. Consequently, as illustrated in FIG. 14, at “m=4”, the waveform integrity tending to decrease, specifically the high frequency component tending to decrease was observed.

For example, in expression (8), “m=2” and “m=4” are timings that are symmetric to each other with respect to “ 3/6” corresponding to the center timing of the clock signal CK, and means an equivalent condition. However, for example, in actual clock driver circuits included in the memory interfaces, the rise waveform and the fall waveform of the clock signal CK may be asymmetric to each other, and thus, either “m=2” or “m=4” is a condition to be avoided. That is, the timing in the clock driver circuits under the simulations was, by coincidence, “m=4”.

By the application of the distance Lm between two memory devices ME as described in the first embodiment, the symmetric waveforms was provided for the clock signals CK observed at the input terminals of the two memory devices ME. As a result of observing the waveforms of the chip select signals CS operating in the SDR mode under the simulations, only slight decrease in the waveform integrity was observed at “n=0” as well as “m=3” at which the wiring length LLC is short as illustrated in FIG. 14.

To the contrary, the command address signals CA operate in the 2N mode, and thus, have a slightly different result. As described above, the reflected signals in the 2N mode are canceled for every two round-trip propagations between two memory devices ME. It is assumed herein that the wiring length LLC of FIG. 13 is twice the distance Lm between two memory devices ME, in other words, a condition of “n=2” as well as “m=0” in expression (8) is assumed.

By using the wiring length LLc, the condition of cancelling the reflected signals in the command address signal CA is also met as similar to that of the chip select signal CS. That is, the reflected signals are additionally canceled between the control device CTL and the memory device ME1 closer thereto in one unit of one round-trip propagation of the command address signal CA. Consequently, the waveform integrity is slightly improved. The signal shift in one unit of one cycle also provides the same phenomenon, and thus, the condition of cancelling the reflected signals is met at “n=(even number)” as well as “m=0.” That is, the optimum condition is at “n=(even number)” as well as “m=0”.

It is then assumed that the wiring length LLC of FIG. 13 is equal to the distance Lm between two memory devices ME for the command address signal CA, in other words, a condition of “n=1” as well as “m=0” in expression (8) is assumed. By using the wiring length LLC, the condition of cancelling the reflected signals is undesirably met between the control device CTL and the memory device ME2 farther from it. In this case, the less reflected signals are propagated from the memory device ME2 farther from the control device CTL to the memory device ME1 closer to it, and thus, the effect of cancelling the reflected signals is not sufficient in the memory device ME1 closer thereto, and the waveform integrity may decrease. The same phenomenon is caused even in the signal shift in one unit of one cycle.

As described above, the conditions to be avoided for the command address signal CA are at “n=(odd number)” as well as “m=0” as illustrated in FIG. 14. As similar to the chip select signal CS, as a result of observing the waveforms of the command address signal CA under the simulations, the decrease in the waveform integrity was observed at a point of shift by half the distance Lm from the optimum conditions “n=(even number)” as well as “m=0”. Thus, additional conditions to be avoided are at “n=(even number)” as well as “m=3” as illustrated in FIG. 14.

### Principal Effect of Second Embodiment

Similar effects to various effects of the first embodiment can be provided by using the electronic device according to the second embodiment. Additionally, in the second embodiment, the wiring length between the control device and the memory device closer to it is limited. This manner can suppress the phenomena that is the interference of the effect of cancelling the reflected signals between the memory devices which are adjacent to each other. Consequently, the waveform integrity can be further improved. Furthermore, since the wiring length of the clock signal CK, which is not in direct connection with the effect of cancelling the reflected signals, is limited, the signal waveform integrity can be further improved.

What is claimed is:

1. An electronic device comprising:
a wiring substrate having a first surface, a second surface opposite the first surface, a plurality of wiring layers and a plurality of wirings;
a first memory device mounted on the first surface;
a second memory device mounted on the first surface;
a third memory device mounted on the second surface;
a fourth memory device mounted on the second surface; and
a control device mounted on the first surface, the control device being configured to access each of the first memory device and the second memory device by using a common first clock signal and a common first chip select signal, and the control device being configured to access each of the third memory device and the fourth memory device by using a common second clock signal and a common second chip select signal,
wherein the plurality of wirings includes:
a plurality of first wirings through which the common first clock signal and the common first chip select signal are propagated; and
a plurality of second wirings through which the common second clock signal and the common second chip select signal are propagated,
wherein the plurality of first wirings is provided in a wiring layer, which is closer to the first surface than the second surface, of the plurality of wiring layers, and
wherein the plurality of second wirings is provided in a wiring layer, which is closer to the second surface than the first surface, of the plurality of wiring layers.

2. The electronic device according to claim 1,
wherein when it is assumed that each of a cycle of the common first clock signal and a cycle of the common second clock signal is “Tck” and that each of a distance between the first memory device and the second memory device and a distance between the third memory device and the fourth memory device is “Lm”, “Lm” is defined based on a propagation delay time of “Tck/2”.

3. The electronic device according to claim 1,
wherein, in a gap between the first surface and the second surface, the wiring substrate includes a plurality of through via wirings each penetrating through the plurality of wiring layers,
wherein the plurality of through via wirings includes:
a first through via wiring connecting the first wiring with one of the first memory device and the second memory device; and
a second through via wiring connecting the second wiring with one of the third memory device the fourth memory device,
wherein the first through via wiring includes:
a first via section between a connecting point with the first wiring and the first surface; and
a first open stub between the connecting point with the first wiring and the second surface,
wherein the second through via wiring includes:
a second via section between a connecting point with the second wiring and the second surface; and
a second open stub between the connecting point with the second wiring and the first surface,
wherein a length of the first via section is less than a length of the first open stub, and
wherein a length of the second via section is less than a length of the second open stub.

4. The electronic device according to claim 3,
wherein when it is assumed that each of a cycle of the common first clock signal and a cycle of the common second clock signal is “Tck”, that each of a distance between the first memory device and the second memory device and a distance between the third memory device and the fourth memory device is “Lm”, and that each of a propagation delay time of the first via section and a propagation delay time of the second via section is “τᵥₐ”, “Lm” is defined based on a propagation delay time of “Tck/2−τᵥₐ”.

5. The electronic device according to claim 3,
wherein when it is assumed that a wavelength of a propagation signal propagating through each of the first wiring and the second wiring is “λ”, each of the length of the first open stub and the length of the second open stub is less than “λ/4”.

6. The electronic device according to claim 3,
wherein when the common first clock signal propagates the first through via wiring and the common second clock signal propagates the second through via wiring, the length of the first via section and the length of the second via section are equal to each other, and
wherein when the common first chip select signal propagates the first through via wiring and the common second chip select signal propagates the second through via wiring, the length of the first via section and the length of the second via section are equal to each other.

7. The electronic device according to claim 2,
wherein the control device is configured to access each of the first memory device, the second memory device, the third memory device and the fourth memory device by using a common command address signal, and
wherein the common command address signal is set as a 2N mode that operates as one unit of two cycles of one of the common first clock signal and the common second clock signal.

8. The electronic device according to claim 7,
wherein, in a gap between the first surface and the second surface, the wiring substrate includes a plurality of through via wirings each penetrating through the plurality of wiring layers,
wherein the plurality of through via wirings includes a third through via wiring connecting a wiring through which the common command address signal is propagated with each of the first memory device and the third memory device, and
wherein when it is assumed that each of the cycle of the common first clock signal and the cycle of the common second clock signal is “Tck”, that a wiring length between an external terminal configured to output the common command address signal from the control device and the third through via wiring is “LLC,” and that “n” is an even number, “LLc” is defined based on a propagation delay time of “(Tck/2)×n”.

9. The electronic device according to claim 2,
wherein even-number memory devices including the first memory device and the second memory device and configured to be accessed by using the common first clock signal and the common first chip select signal are mounted on the first surface,
wherein even-number memory devices including the third memory device and the fourth memory device and configured to be accessed by using the common second clock signal and the common second chip select signal are mounted on the second surface, and
wherein when it is assumed that a distance between two memory devices, which are adjacent to each other, of the even-number memory devices mounted on the first surface is “Lm” and that a distance between two memory devices the even-number memory devices mounted on the second surface is “Lm”, “Lm” is defined based on a propagation delay time of “Tck/2”.

10. The electronic device according to claim 1, further comprising:
a fifth memory device and a sixth memory device mounted on the first surface; and
a seventh memory device and an eighth memory device mounted on the second surface,
wherein the control device includes:
a first memory interface configured to access each of the first memory device and the second memory device by using the common first clock signal and the common first chip select signal, and configured to access each of the third memory device and the fourth memory device by using the common second clock signal and the common second chip select signal; and
a second memory interface configured to access each of the fifth memory device and the sixth memory device by using a common third clock signal and a common third chip select signal, and configured to access each of the seventh memory device and the eighth memory device by using a common fourth clock signal and a common fourth chip select signal, and
wherein an external terminal of the second memory interface is located closer to an inside of the control device than an external terminal of the first memory interface.

11. An electronic device comprising:
a wiring substrate having a first surface, a second surface opposite the first surface, a plurality of wiring layers and a plurality of wirings;
a first memory device mounted on the first surface;
a second memory device mounted on the first surface; and
a control device mounted on the first surface or the second surface, the control device being configured to access each of the first memory device and the second memory device by using a common clock signal and a common chip select signal,
wherein when it is assumed that each of a cycle of the common first clock signal and a cycle of the common second clock signal is “Tck” and that a distance between the first memory device and the second memory device is “Lm”, “Lm” is defined based on a propagation delay time of “Tck/2”.

12. The electronic device according to claim 11,
wherein the wiring substrate includes:
a plurality of first wirings being some of the plurality of wirings and configured to propagate the common clock signal and the common chip select signal; and
a first through via wiring provided to penetrate the plurality of wiring layers between the first surface and the second surface and configured to connect the first wiring with one of the first memory device and the second memory device, and
wherein the first through via wiring includes:
a first via section between a connecting point with the first wiring and the first surface; and
a first open stub between the connecting point with the first wiring and the second surface.

13. The electronic device according to claim 12,
wherein when it is assumed that a propagation delay time of the first via section is “τᵥₐ”, “Lm” is defined based on a propagation delay time of “Tck/2−τᵥₐ”.

14. The electronic device according to claim 12,
wherein a length of the first via section is less than a length of the first open stub.

15. The electronic device according to claim 14,
wherein when it is assumed that a wavelength of a propagation signal propagating through the first wiring is λ, a length of the first open stub is less than “λ/4”.
